(19) United States
(12) Patent Application Publication
(10) Pub. No.: US 2010/0133349 A1
(43) Pub. Date: Jun. 3, 2010

(54) Semiconductor package, method of manufacturing semiconductor package, electronic component, and method of manufacturing electronic component

(75) Inventor: Tadayuki Shingai, Kumamoto (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: NEC ELECTRONICS CORPORATION, Kawasaki-shi (JP)

(21) Appl. No.: 12/591,729

(22) Filed: Nov. 30, 2009

(30) Foreign Application Priority Data
Dec. 1, 2008 (JP) 2008-306011

(51) Int. Cl. G06K 19/07; H01L 23/552; H01Q 17/00; H01L 21/56

(52) U.S. Cl. 235/492; 257/659; 29/601; 438/124; 257/E21.502; 257/E23.114

(57) ABSTRACT

A semiconductor package includes a semiconductor chip, a die pad being mounted with the semiconductor chip with a dielectric interposed therebetween and serving as an antenna, and a molding resin (sealing resin) sealing the semiconductor chip and the die pad. The relative dielectric constant of the dielectric is higher than that of the sealing resin.

The application is based on Japanese patent application No. 2008-306011, the content of which is incorporated hereinto by reference.

### BACKGROUND

1. Technical Field

The present invention relates to a semiconductor package, a method of manufacturing the semiconductor package, an electronic component, and a method of manufacturing the electronic component.

2. Related Art

For example, a semiconductor package described in Japanese Unexamined Patent Publication No. 2005-346412 has been known as a semiconductor package having a semiconductor chip and an antenna.

FIG. 10 is a plan view illustrating the semiconductor package 10 described in Japanese Unexamined Patent Publication No. 2005-346412. The semiconductor package shown in FIG. 10 has a first semiconductor chip 11 such as a central processing unit (CPU) or a memory and a second semiconductor chip 12 storing an identifier, both of which are built over a lead frame 13, and the identifier is read in a non-contact manner. The semiconductor package 10 has a structure in which a slit 30 is formed in a part of the lead frame 13 and is used as an antenna 15.

Another example of the semiconductor package is disclosed in Japanese Unexamined Patent Publication No. 2006-237450.

However, the present inventor has recognized that the electric field strength of RF waves transmitted from the antenna in the package is attenuated in the package when the semiconductor package having an antenna wirelessly communicates with an external device physically apart from the semiconductor package. This is because neighboring metals such as leads, wires, and semiconductor chips interfere with each other. A general sealing resin contains carbon and has a characteristic of absorbing the RF waves. Accordingly, the electric field strength of the RF waves is further attenuated when the semiconductor chip or the antenna is sealed with the sealing resin.

### SUMMARY

In an embodiment of the invention, there is provided a semiconductor package including: a semiconductor chip; a die pad being mounted with the semiconductor chip with a dielectric interposed therebetween and serving as an antenna; and a sealing resin sealing the semiconductor chip and the die pad, wherein a relative dielectric constant of the dielectric is higher than that of the sealing resin.

In another embodiment of the invention, there is provided a semiconductor package including: a first semiconductor chip; a die pad being mounted with the first semiconductor chip with a dielectric interposed and serving as an antenna; a suspension lead connected to the die pad; a second semiconductor chip mounted on the suspension lead and storing an identifier; and a sealing resin sealing the first and second semiconductor chips and the die pad, wherein a relative dielectric constant of the dielectric is higher than that of the sealing resin.

In another embodiment of the invention, there is provided an electronic component including: a mounting board; and a semiconductor package mounted on the mounting board, wherein the semiconductor package includes: a semiconductor chip; a die pad being mounted with the semiconductor chip with a dielectric interposed therebetween and serving as an antenna; and a sealing resin sealing the semiconductor chip and the die pad, wherein a relative dielectric constant of the dielectric is higher than that of the sealing resin.

In another embodiment, there is provided an electronic component including: a mounting board; and a semiconductor package mounted on the mounting board, wherein the semiconductor package includes: a first semiconductor chip; a die pad being mounted with the first semiconductor chip with a dielectric interposed and serving as an antenna; a suspension lead connected to the die pad; a second semiconductor chip mounted on the suspension lead and storing an identifier; and a sealing resin sealing the first and second semiconductor chips and the die pad, and wherein a relative dielectric constant of the dielectric is higher than that of the sealing resin.

In another embodiment of the invention, there is provided a method of manufacturing a semiconductor package, including: mounting a semiconductor chip on a die pad serving as an antenna with a dielectric interposed; and sealing the semiconductor chip and the die pad with a sealing resin, wherein a relative dielectric constant of the dielectric is higher than that of the sealing resin.

In another embodiment of the invention, there is provided a method of manufacturing a semiconductor package, including: preparing a die pad serving as an antenna and a suspension lead connected to the die pad; mounting a first semiconductor chip on the die pad with a dielectric interposed; mounting a second semiconductor chip storing an identifier on the suspension lead; and sealing the first and second semiconductor chips and the die pad with a sealing resin, wherein a relative dielectric constant of the dielectric is higher than that of the sealing resin.

In another embodiment of the invention, there is provided a method of manufacturing an electronic component, including: preparing a mounting board; and mounting a semiconductor package on the mounting board, wherein the semiconductor package includes: a semiconductor chip; a die pad being mounted with the semiconductor chip with a dielectric interposed and serving as an antenna; and a sealing resin sealing the semiconductor chip and the die pad, and wherein a relative dielectric constant of the dielectric is higher than that of the sealing resin.

In another embodiment of the invention, there is provided a method of manufacturing an electronic component, including: preparing a mounting board; and mounting a semiconductor package on the mounting board. Here, the semiconductor package includes: a first semiconductor chip; a die pad being mounted with the first semiconductor chip with a dielectric interposed and serving as an antenna; a suspension lead connected to the die pad; a second semiconductor chip mounted on the suspension lead and storing an identifier; and a sealing resin sealing the first and second semiconductor chips and the die pad, and wherein a relative dielectric constant of the dielectric is higher than that of the sealing resin.

According to the invention, the dielectric having a relative dielectric constant higher than that of the sealing resin is disposed between the die pad having an antenna function and the semiconductor chip. Accordingly, it is possible to suppress the absorption of the RF waves in the semiconductor chip. As a result, it is possible to effectively suppress the attenuation of the electric field strength of the RF waves emitted from the package.

According to the invention, it is possible to effectively suppress the attenuation of the electric field strength of the RF waves emitted from the package.

### BRIEF DESCRIPTION OF THE DRAWINGS

The above and other objects, advantages, and features of the present invention will be more apparent from the following description of certain preferred embodiments taken in conjunction with the accompanying drawings, in which:

FIG. 1 is a plan (perspective) view schematically illustrating a semiconductor package according to an embodiment of the invention;

FIG. 2A is a sectional view taken along line A-A′ of the semiconductor package according to the embodiment of the invention, FIG. 2B is a sectional view taken along line B-B′ of the semiconductor package according to the embodiment, FIG. 2C is a modified example of a sectional view taken along line B-B′ of the semiconductor package according to the embodiment, FIG. 2D is a modified example of a sectional view taken along line A-A′ of the semiconductor package according to the embodiment;

FIG. 3 is an enlarged view of the semiconductor package according to the embodiment of the invention;

FIG. 4 is a diagram illustrating the configuration of a transmitter using a semiconductor device having the semiconductor package according to the embodiment of the invention and a receiver communicating with the transmitter;

FIGS. 5A to 5C are diagrams illustrating a method of manufacturing the semiconductor package according to the embodiment of the invention;

FIGS. 6A to 6C are diagrams illustrating an advantage of the semiconductor package according to the embodiment of the invention;

FIGS. 7A to 7D are diagrams illustrating a modified example of the semiconductor package according to the embodiment of the invention;

FIG. 8 is a diagram illustrating another modified example of the semiconductor package according to the embodiment of the invention;

FIG. 9 is a diagram illustrating another modified example of the semiconductor package according to the embodiment of the invention; and

FIG. 10 is a plan view illustrating a semiconductor package according to a related art.

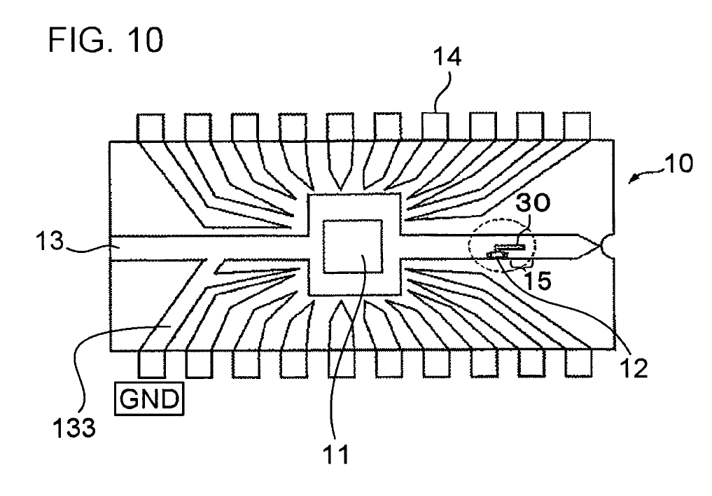

### DETAILED DESCRIPTION

The invention will be now described herein with reference to illustrative embodiments. Those skilled in the art will recognize that many alternative embodiments can be accomplished using the teachings of the present invention and that the invention is not limited to the embodiments illustrated for explanatory purposes.

Hereinafter, preferred embodiments of the invention will be described with reference to the accompanying drawings. In all the drawings, like elements are referenced by like reference numerals and descriptions thereof will not be repeated.

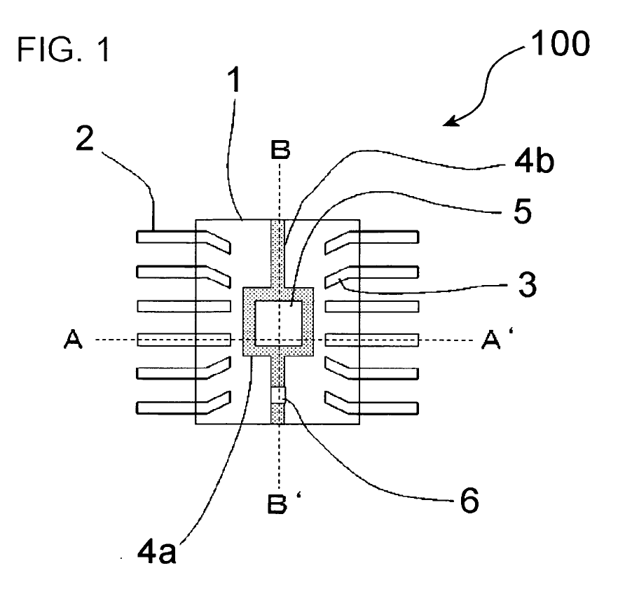

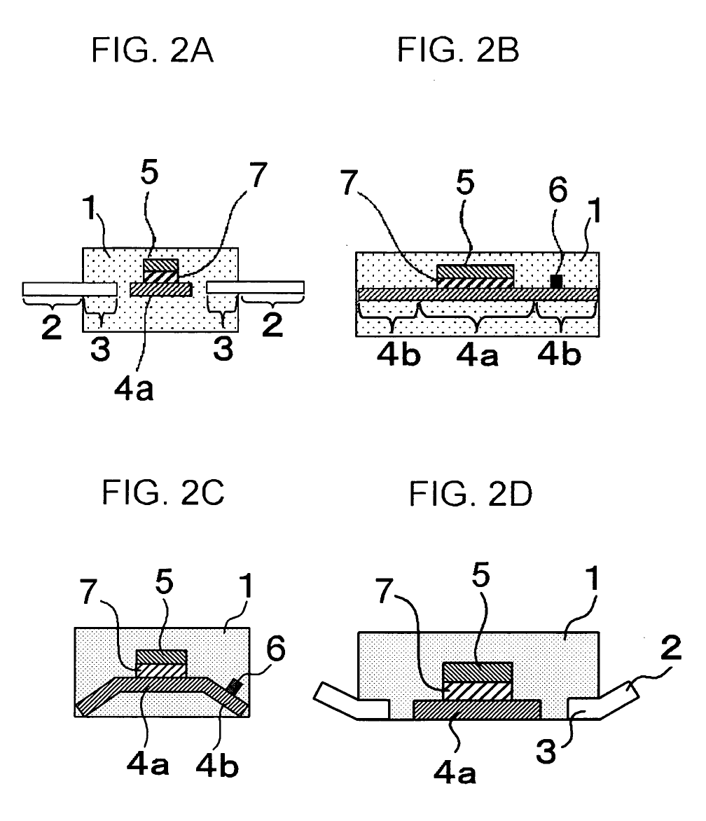

FIG. 1 is a plan (perspective) view schematically illustrating a semiconductor package 100 according to an embodiment of the invention. FIGS. 2A and 2D are sectional views taken along line A-A′ of the semiconductor package 100 shown in FIG. 1 and FIGS. 2B and 2C are sectional views taken along line B-B′ of the semiconductor package 100 shown in FIG. 1.

The semiconductor package 100 includes a semiconductor chip 5 (first semiconductor chip), a die pad 4a being mounted with the semiconductor chip 5 with a dielectric 7 interposed therebetween and serving as an antenna, a suspension lead 4b connected to the die pad, and a molding resin (sealing resin) 1 sealing the semiconductor chip 5, the die pad 4a, and the suspension lead 4b. The relative dielectric constant of the dielectric 7 is higher than that of the molding resin 1. The molding resin 1 can be formed of, for example, epoxy resin.

The semiconductor package 100 includes leads (outer leads 2 and inner leads 3) and a communication element 6.

As shown in the drawings, the die pad 4a and the suspension lead 4b are connected to each other. The suspension lead 4b also serves as an antenna along with the die pad 4a. The communication element 6 is mounted on the suspension lead 4b. The communication element 6 is a semiconductor chip (second semiconductor chip) storing an identifier and having a communication function. Specifically, the communication element 6 is a radio frequency identification (RFID) chip wirelessly communicating with an external device. The communication element 6 is also sealed with the molding resin 1.

The semiconductor chip 5 generates and amplifies a signal to generate RF waves. The generated RF waves are transmitted from the die pad 4a and the suspension lead 4b to the communication element 6 and are transmitted from the communication element 6 to the outside. The communication element 6 is mounted on the suspension lead 4b apart from the semiconductor chip 5. Accordingly, it is possible to suppress the interference between metals constituting the semiconductor chip 5. It is also possible to suppress the attenuation of the electric field strength resulting from the interference of magnetic noises generated by the operation of the semiconductor chip 5 with the RF waves emitted from the antenna.

The semiconductor chip 5 may be, for example, a micro computer, a memory, an application specific integrated circuit (ASIC), or the like. The semiconductor chip 5 is connected to the inner leads 3 by wires (not shown).

No potential, including a ground potential, is applied to the die pad 4a. Accordingly, as shown in FIG. 2B, the suspension lead 4b may not be exposed from the molding resin 1.

As shown in FIG. 2C, the suspension lead 4b may be folded and bent in a direction in which the semiconductor chip 5 and the communication element 6 apart from each other. Accordingly, it is possible to separate the communication element 6 and the semiconductor chip 5. Therefore, it is possible to effectively three-dimensionally use a space in the package. As shown in FIG. 2D, the die pad 4a may be exposed and the outer leads 2 may be folded and bent in the opposite direction to the exposed surface of the die pad 4a.

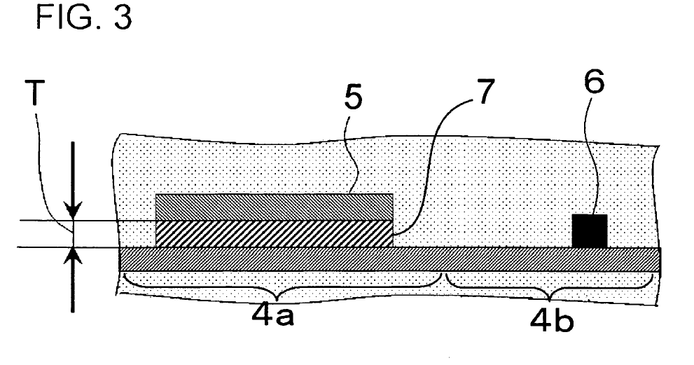

FIG. 3 is an enlarged view of FIG. 2B. The thickness of the dielectric 7 is denoted by T. The dielectric 7 is secured to the bottom surface of the semiconductor chip 5 and the top surface of the die pad 4a with an adhesive layer (not shown). For example, a silver paste is used as the adhesive.

The relative dielectric constant of the dielectric 7 may be specifically set to be equal to or more than 5 and equal to or less than 15. When the relative dielectric constant of the dielectric 7 is excessively small, it is not possible to satisfactorily suppress the attenuation of the electric field strength. On the other hand, when the relative dielectric constant of the dielectric 7 is excessively large, it affects the wavelength, thereby reducing the size of the suspension lead 4b. Therefore, the directionality is degraded, thereby making it difficult to receive the RF waves from an external device. Ceramics or glass may be used as the material of the dielectric 7.

The thickness T of the dielectric 7 can be set to be equal to or more than 300 μm and equal to or less than 900 μm. When T is excessively small, the distance between the semiconductor chip 5 and the die pad 4a is reduced. Accordingly, it is not possible to suppress the interference of the metals constituting the semiconductor chips 5. The antenna performance of the die pad 4a or the suspension lead 4b is reduced with the operation of the semiconductor chip 5. Therefore, it is not possible to satisfactorily suppress the attenuation of the electric field strength. On the other hand, when T is excessively large, the balance in the package is lost at the time of the sealing with the molding resin 1 and thus the wires or the die pad 4a may be exposed from the surface of the package.

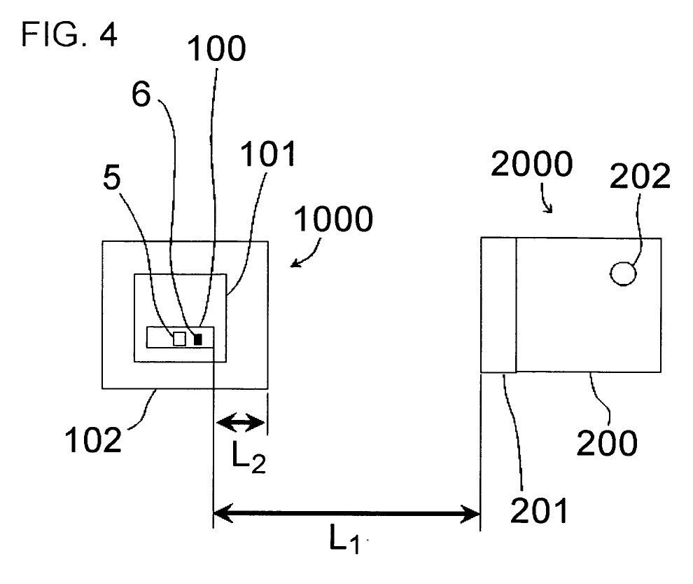

FIG. 4 is a diagram illustrating the configuration of a transmitter 1000 having a semiconductor package 100 mounted on a circuit board (mounting board) 101 and a receiver 200 communicating with the transmitter 1000. In the transmitter 1000, the semiconductor package 100 and the circuit board 101 are received in a chassis 102. The receiver 200 is disposed in an external device 2000 located apart from the transmitter 1000.

The external device 2000 includes the receiver 200, an antenna 201, and a light emitting diode (LED) 202. When the RF waves transmitted from the transmitter 1000 are received by the receiver 200, the LED 202 emits light. In this way, it can be seen that the external device 2000 is in communication.

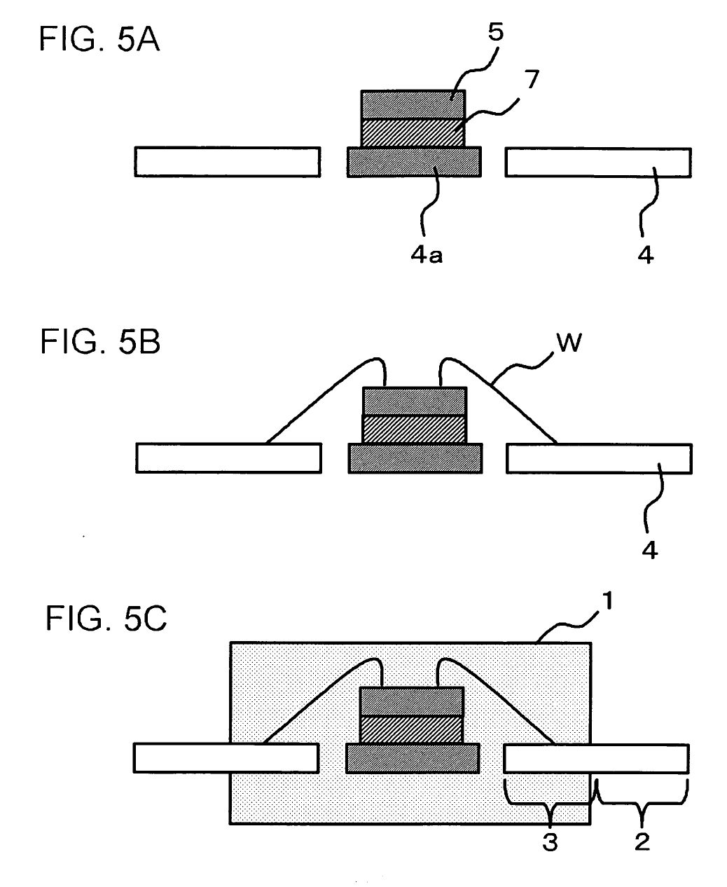

A method of manufacturing the semiconductor package 100 will be described now with reference to FIGS. 5A to 5C. First, an adhesive is applied to the bottom surface of the dielectric 7 or the die pad 4a to secure the dielectric 7 to the die pad 4a. Then, an adhesive is applied to the top surface of the dielectric 7 and the semiconductor chip 5 is mounted on the adhesive (FIG. 5A). The semiconductor chip 5 and the leads 4 are connected with wires W (FIG. 5B). The communication element 6 is mounted on the suspension lead 4b and the resultant structure other than the outer leads 2 is sealed with the molding resin 1 (FIG. 5C).

The operational advantages of this embodiment will be described now. In the semiconductor package 100, the dielectric having a relative dielectric constant higher than that of the molding resin 1 is disposed between the die pad 4a having an antenna function and the semiconductor chip 5. Accordingly, it is possible to suppress the absorption of the RF waves in the semiconductor chip 5. Therefore, it is possible to effectively suppress the attenuation of the electric field strength of the RF waves output from the package.

The relative dielectric constant of the molding resin 1 is set to be smaller than, for example, 5. Here, by setting the relative dielectric constant of the dielectric 7 to be equal to or more than 5, it is possible to set the relative dielectric constant of the dielectric 7 to be greater than the relative dielectric constant of the molding resin 1.

When the thickness of the dielectric 7 is excessively small, the inner leads 3 or the wires W adjacent to each other in the package may be deformed to get close to each other or the semiconductor chip 5 may be affected by a magnetic noise. Accordingly, the electric field strength of the RF waves is attenuated by the metal interference. Therefore, by setting the thickness T of the dielectric 7 to be equal to or more than 300 μm, it is possible to reduce the influence of the magnetic noise in the horizontal direction.

The advantages obtained by controlling the relative dielectric constant and the thickness of the dielectric 7 in the package 100 will be described now in detail.

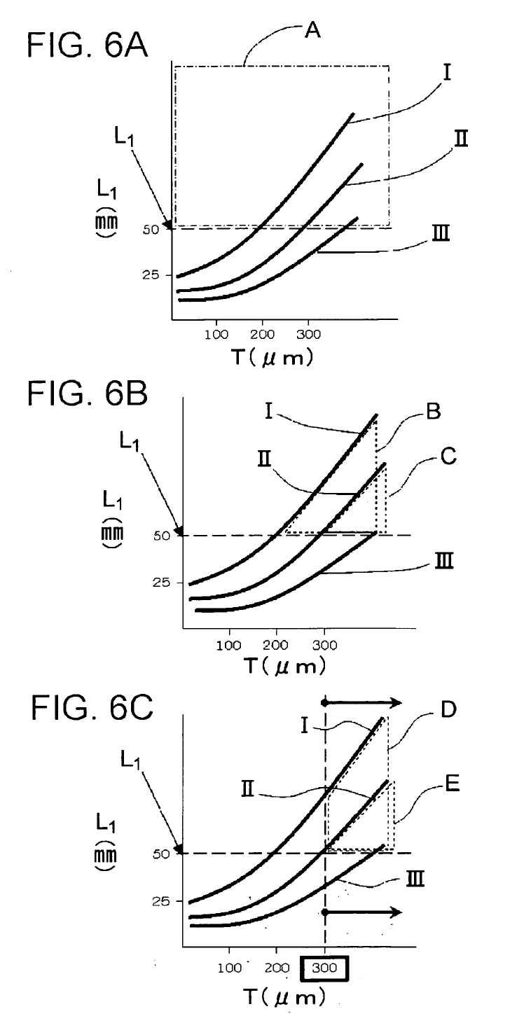

FIGS. 6A to 6C are graphs illustrating the relation of the distance L₁ between the semiconductor package 100 and the receiver 200 and the thickness T of the dielectric in communication between the transmitter 1000 and the receiver 200. The curves of the graphs represent the maximum communicable distances L₁ (see FIG. 4). Accordingly, in the graphs, communication is possible in the distance zones below the curves but communication is not possible in the distance zones above the curves. This is because the electric field strength is attenuated and thus the RF waves cannot be received and detected by the receiver 200 when the distance increases.

In consideration of the fact that the semiconductor package 100 is mounted on or inserted into the circuit board 101 and the layout around the circuit board 101 or the structure of the chassis 102, the distance L₂ (see FIG. 4) between the semiconductor package 100 and the chassis 102 should be equal to or more than 50 mm. Accordingly, to enable the above communication, the distance L₁ between the semiconductor package 100 and the receiver 200 should be set to be equal to or more than 50 mm. Therefore, area A in FIG. 6A is a communicable zone.

In FIGS. 6A to 6C, the measurement results of the maximum communicable distance L₂ when the relative dielectric constant of the dielectric 7 is changed to 10 (glass (I)), 5 (ceramics (II)), and 2.5 (silicon (III)) are represented by the curves. As described above, since communication is possible in the distance zones below the curves, communication is possible in the distance zone of area B in FIG. 6B when the relative dielectric constant of the dielectric 7 is 10.0 (I). When the relative dielectric constant of the dielectric 7 is 5.0 (II), communication is possible in the distance zone of area C. However, when the relative dielectric constant of the dielectric 7 is 2.5 (I), the curve is located in the distance zone below L₂=50 mm, and thus it is not possible to set the communicable distance L₁.

As a result, when the relative dielectric constant of the dielectric 7 is equal to or more than 5, the distance equal to or more than L₁=50 mm can be guaranteed and thus it is possible to set the communicable distance L₁ using the present package technique. At this time, the thickness T of the dielectric 7 is equal to or more than 300 μm. That is, when the relative dielectric constant of the dielectric 7 is equal to or more than 5 and the thickness T is equal to or more than 300 μm, it is possible to set the communicable distance L₁.

That is, as shown in FIG. 6C, when the relative dielectric constant of the dielectric 7 is 10 (I), communication is possible in the distance zone of area D. When the relative dielectric constant of the dielectric 7 is 5 (II), communication is possible in the distance zone of area E. Therefore, by setting the thickness T of the dielectric 7 to be equal to or more than 300 μm and setting the relative dielectric constant to be equal to or more than 5, it is possible to effectively suppress the attenuation of the electric field strength using the present package technique. Therefore, it is possible to guarantee the detection distance between the transmitter 1000 and the receiver 200.

Although the embodiments of the invention have been described with reference to the accompanying drawings, the embodiments are only examples of the invention and various other configurations may be employed.

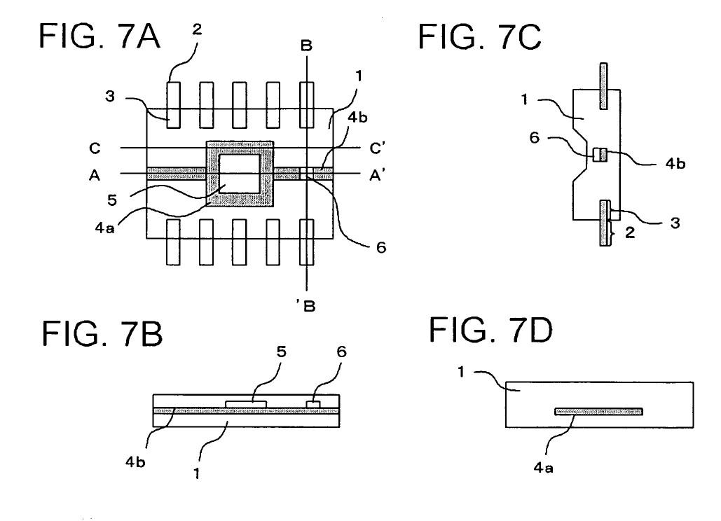

For example, the thickness of the molding resin 1 around the communication element 6 or the suspension lead 4b may be reduced. In this way, it is possible to further prevent the attenuation of the electric field strength. FIG. 7A is a plan view illustrating a modified example of the semiconductor package according to the embodiment of the invention, FIG. 7B is a sectional view taken along line A-A′ of FIG. 7A, FIG. 7C is a sectional view taken along line B-B′ of FIG. 7A, and FIG. 7D is a sectional view taken along line C-C′ of FIG. 7A. As shown in FIGS. 7B to 7D, the thickness of the molding resin 1 over the communication element 6 and the suspension lead 4b may be reduced. The shaping direction of the leads may be inverted and the resin thickness around the inner leads 3 instead of the semiconductor chip 5 may be reduced.

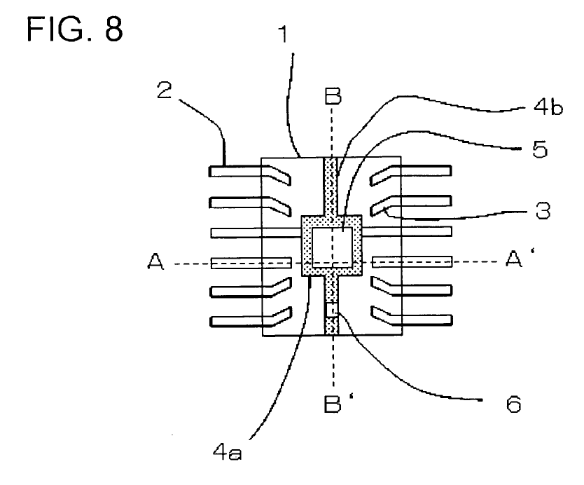

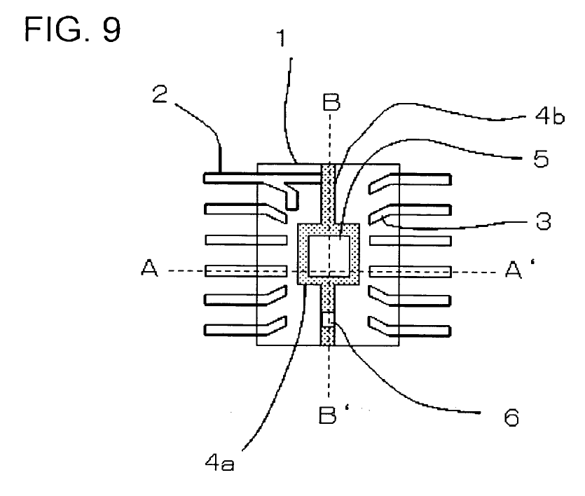

In the semiconductor package 100 shown in FIG. 1, a configuration in which the outer leads 2 or the inner leads 3 are connected to the ground (GND) may be employed. That is, as shown in FIG. 8, the configuration in which at least one of the outer leads 2 is connected to the die pad 4a may be employed. As shown in FIG. 9, the configuration in which at least one of the outer leads 2 is connected to the suspension lead 4b may be employed.

The semiconductor package according to the invention can be introduced as electronic components into various communication apparatuses by mounting the semiconductor package on a mounting board. The communication apparatus may be the transmitter described in the above embodiment, and more specifically, examples thereof include a mobile phone, a PDA, a portable navigation apparatus, and a notebook PC.

It is apparent that the present invention is not limited to the above embodiment, and may be modified and changed without departing from the scope and spirit of the invention.

What is claimed is:

1. A semiconductor package comprising:
a semiconductor chip;
a die pad being mounted with said semiconductor chip with a dielectric interposed and serving as an antenna; and
a sealing resin sealing said semiconductor chip and said die pad,
wherein a relative dielectric constant of said dielectric is higher than that of said sealing resin.

2. The semiconductor package as set forth in claim 1, further comprising a suspension lead connected to said die pad,
wherein said sealing resin seals said suspension lead.

3. The semiconductor package as set forth in claim 1, wherein said relative dielectric constant of said dielectric is equal to or more than 5 and equal to or less than 15.

4. The semiconductor package as set forth in claim 1, wherein the thickness of said dielectric is equal to or more than 300 μm and equal to or less than 900 μm.

5. A semiconductor package comprising:
a first semiconductor chip;
a die pad being mounted with said first semiconductor chip with a dielectric interposed and serving as an antenna;
a suspension lead connected to said die pad;
a second semiconductor chip mounted on said suspension lead and storing an identifier; and
a sealing resin sealing said first and second semiconductor chips and said die pad,
wherein a relative dielectric constant of said dielectric is higher than that of said sealing resin.

6. The semiconductor package as set forth in claim 5, wherein said relative dielectric constant of said dielectric is equal to or more than 5 and equal to or less than 15.

7. The semiconductor package as set forth in claim 5, wherein the thickness of said dielectric is equal to or more than 300 μm and equal to or less than 900 μm.

8. The semiconductor package as set forth in claim 5, wherein said second semiconductor chip has a communication function.

9. An electronic component comprising:
a mounting board; and
a semiconductor package mounted on said mounting board,
wherein said semiconductor package includes:
a semiconductor chip;
a die pad being mounted with said semiconductor chip with a dielectric interposed and serving as an antenna; and
a sealing resin sealing said semiconductor chip and said die pad, and
wherein a relative dielectric constant of said dielectric is higher than that of said sealing resin.

10. An electronic component comprising:
a mounting board; and
a semiconductor package mounted on said mounting board,
wherein said semiconductor package includes:
a first semiconductor chip;
a die pad being mounted with said first semiconductor chip with a dielectric interposed and serving as an antenna;
a suspension lead connected to said die pad;
a second semiconductor chip mounted on said suspension lead and storing an identifier; and
a sealing resin sealing said first and second semiconductor chips and said die pad, and
wherein a relative dielectric constant of said dielectric is higher than that of said sealing resin.

11. The electronic component as set forth in claim 10, wherein said second semiconductor chip has a communication function.

12. A method of manufacturing a semiconductor package, comprising:
mounting a semiconductor chip on a die pad serving as an antenna with a dielectric interposed; and
sealing said semiconductor chip and said die pad with a sealing resin,
wherein a relative dielectric constant of said dielectric is higher than that of said sealing resin.

13. A method of manufacturing a semiconductor package, comprising:
preparing a die pad serving as an antenna and a suspension lead connected to said die pad;
mounting a first semiconductor chip on said die pad with a dielectric interposed;
mounting a second semiconductor chip storing an identifier on said suspension lead; and
sealing said first and second semiconductor chips and said die pad with a sealing resin,
wherein a relative dielectric constant of said dielectric is higher than that of said sealing resin.

14. The method as set forth in claim 13, further comprising giving a communication function to said second semiconductor chip.

15. A method of manufacturing an electronic component, comprising:
preparing a mounting board; and
mounting a semiconductor package on said mounting board,
wherein said semiconductor package includes:
a semiconductor chip;
a die pad being mounted with said semiconductor chip with a dielectric interposed and serving as an antenna; and
a sealing resin sealing said semiconductor chip and said die pad, and
wherein a relative dielectric constant of said dielectric is higher than that of said sealing resin.

16. A method of manufacturing an electronic component, comprising:
preparing a mounting board; and
mounting a semiconductor package on said mounting board,
wherein said semiconductor package includes:
a first semiconductor chip;
a die pad being mounted with said first semiconductor chip with a dielectric interposed and serving as an antenna;
a suspension lead connected to said die pad;
a second semiconductor chip mounted on said suspension lead and storing an identifier; and
a sealing resin sealing said first and second semiconductor chips and said die pad, and
wherein a relative dielectric constant of said dielectric is higher than that of said sealing resin.

17. The method as set forth in claim 16, wherein said second semiconductor chip has a communication function.
